(19) United States
(12) Patent Application Publication
(10) Pub. No.: US 2025/0040226 A1
(43) Pub. Date: Jan. 30, 2025

(54) SEMICONDUCTOR DEVICE AND METHOD OF MANUFACTURING SEMICONDUCTOR DEVICE

(71) Applicant: INSTITUTE OF MICORELECTRONICS, CHINESE ACADEMY OF SCIENCES, Beijing (CN)

(72) Inventors: Junjie LI, Beijing (CN); Gaobo Xu, Beijing (CN); Na Zhou, Beijing (CN); Chenchen Zhang, Beijing (CN); Jianfeng Gao, Beijing (CN); Yihong Lu, Beijing (CN); Tao Yang, Beijing (CN); Junfeng Li, Beijing (CN); Jun Luo, Beijing (CN); Rui Chen, Beijing (CN)

(21) Appl. No.: 18/786,010

(22) Filed: Jul. 26, 2024

(30) Foreign Application Priority Data
Jul. 26, 2023 (CN) 202310927337.6

(51) Int. Cl. H01L 29/423; H01L 29/49

(52) U.S. Cl. CPC H01L 29/4236; H01L 29/42384; H01L 29/4908

(57) ABSTRACT

The present disclosure provides a semiconductor device and a method of manufacturing a semiconductor device. The semiconductor device includes: a substrate; an insulating layer provided with a plurality of trenches extending in a first direction; a first electrode layer and a second electrode layer, where a spacing region is provided between the first electrode layer and the second electrode layer; a semiconductor layer covering bottom portions and sidewalls of all channel trenches, where the channel trenches are at least a part of trench bodies of the trenches located in the spacing region; a gate dielectric layer covering a surface of the semiconductor layer in the channel trenches on a side away from the bottom portions and the sidewalls of the channel trenches; a gate layer, where at least a part of the channel trenches are fully filled with the gate layer.

### CROSS REFERENCE TO RELATED APPLICATION

This application claims priority to Chinese Patent Application No. 202310927337.6, filed on Jul. 26, 2023, the entire content of which is incorporated herein in its entirety by reference.

### TECHNICAL FIELD

The present disclosure relates to a field of semiconductor technology, in particular to a semiconductor device and a method of manufacturing a semiconductor device.

### BACKGROUND

Dynamic Random Access Memory (DRAM) is the most widely used random access memory in the industry, and its mainstream structure is a combination of one Thin Film Transistor (TFT) and one Capacitance, that is, 1T1C. Oxide semiconductor is more and more widely used in TFT due to its excellent off-state current, which leads to a rise of 2T0C (that is, storage is achieved through a combination of two TFTs, without a need for setting of the capacitance) technology in DRAM. However, the oxide semiconductor has a relatively low relative on-state mobility rate of 3 cm²/Vs to 15 cm²/Vs, which leads to a small driving current of a transistor device in a working state, seriously affecting a reading and writing information rate of DRAM.

### SUMMARY

The embodiments of the present disclosure provide a semiconductor device, including: a substrate; an insulating layer provided on a surface of the substrate on a side of the substrate, where the insulating layer is provided with a plurality of trenches extending in a first direction, the plurality of trenches are sequentially arranged in parallel in a second direction, and the first direction and the second direction are directions perpendicular to each other in a plane where the substrate is located; a first electrode layer and a second electrode layer sequentially provided in the first direction on a surface of the insulating layer on a side away from the substrate, where a spacing region is provided between the first electrode layer and the second electrode layer; a semiconductor layer provided on a surface of the first electrode layer on the side away from the substrate and provided on a surface of the second electrode layer on the side away from the substrate, where an orthographic projection of the semiconductor layer on the substrate has an overlapping region with each of an orthographic projection of the first electrode layer on the substrate, an orthographic projection of the second electrode layer on the substrate and an orthographic projection of the spacing region on the substrate, the semiconductor layer covers bottom portions and sidewalls of all channel trenches, and the channel trenches are at least a part of trench bodies of the trenches located in the spacing region; a gate dielectric layer provided on a surface of the semiconductor layer on a side away from the insulating layer, where an orthographic projection of the gate dielectric layer on the substrate has an overlapping region with the orthographic projection of the spacing region on the substrate, the orthographic projection of the gate dielectric layer on the substrate has no overlapping region with each of the orthographic projection of the first electrode layer on the substrate and the orthographic projection of the second electrode layer on the substrate, and the gate dielectric layer covers a surface of the semiconductor layer in the channel trenches on a side away from the bottom portions and the sidewalls of the channel trenches; and a gate layer provided on a surface of the gate dielectric layer on a side away from the semiconductor layer, where an orthographic projection of the gate layer on the substrate has an overlapping region with the orthographic projection of the spacing region on the substrate, and at least a part of the channel trenches are fully filled with the gate layer.

In some embodiments, a width of the trench is in a range of 1 nm to 500 nm.

In some embodiments, a depth of the trench is in a range of 10 nm to 10000 nm.

In some embodiments, a spacing between two adjacent trenches in the second direction is in a range of 1 nm to 500 nm.

In some embodiments, the gate dielectric layer is manufactured based on one of: aluminium oxide Al₂O₃, hafnium dioxide HfO₂, alumina hafnium HfAIO, zirconia hafnium HfZrO, silicon nitride SiN, silicon dioxide SiO₂, and silicon oxynitride SiON.

In some embodiments, each of the gate layer, the first electrode layer, and the second electrode layer is manufactured based on one of: tungsten W, molybdenum Mo, tantalum Ta, titanium nitride TiN, tantalum nitride TaN, gold Au, and platinum Pt.

In some embodiments, the semiconductor layer is manufactured based on one of: indium gallium zinc oxide IGZO, indium tin oxide ITO, silicon Si, germanium Ge, silicon germanide SiGe, gallium nitride GaN, gallium arsenide GaAs, and indium phosphide InP.

In some embodiments, the insulating layer is manufactured based on one of: silicon dioxide SiO₂, silicon nitride SiN, carbon-containing silicon oxide SiCO, and silicon oxynitride SiON.

The embodiments of the present disclosure further provide a method of manufacturing the above-mentioned semiconductor device, including: providing the substrate; manufacturing the insulating layer on the surface of the substrate on the side of the substrate, and providing the plurality of trenches extending in the first direction on the surface of the insulating layer on the side away from the substrate, where the plurality of trenches are sequentially arranged in parallel in the second direction, and the first direction and the second direction are directions perpendicular to each other in the plane where the substrate is located; sequentially manufacturing the first electrode layer and the second electrode layer in the first direction on the surface of the insulating layer on the side away from the substrate, where the spacing region is provided between the first electrode layer and the second electrode layer; manufacturing the semiconductor layer on the surface of the first electrode layer on the side away from the substrate and on the surface of the second electrode layer on the side away from the substrate, where the orthographic projection of the semiconductor layer on the substrate has the overlapping region with each of the orthographic projection of the first electrode layer on the substrate, the orthographic projection of the second electrode layer on the substrate and the orthographic projection of the spacing region on the substrate, the semiconductor layer covers bottom portions and sidewalls of all channel trenches, and the channel trenches are at least the part of trench bodies of the trenches located in the spacing region; manufacturing the gate dielectric layer on the surface of the semiconductor layer on the side away from the insulating layer, where the orthographic projection of the gate dielectric layer on the substrate has the overlapping region with the orthographic projection of the spacing region on the substrate, the orthographic projection of the gate dielectric layer on the substrate has no overlapping region with each of the orthographic projection of the first electrode layer on the substrate and the orthographic projection of the second electrode layer on the substrate, and the gate dielectric layer covers the surface of the semiconductor layer in the channel trenches on the side away from the bottom portions and the sidewalls of the channel trenches; and manufacturing the gate layer on the surface of the gate dielectric layer on the side away from the semiconductor layer, where the orthographic projection of the gate layer on the substrate has the overlapping region with the orthographic projection of the spacing region on the substrate, and at least the part of the channel trenches are fully filled with the gate layer.

In some embodiments, the trenches are provided on the surface of the insulating layer on the side away from the substrate based on one of: a dual patterning and sacrificial layer removal process, a multiple patterning process, and a photolithography process.

### BRIEF DESCRIPTION OF THE DRAWINGS

In order to more clearly describe the technical solutions in one or more embodiments of the present disclosure or the related art, accompanying drawings required in the descriptions of the embodiments of the present disclosure or the related art will be briefly introduced below. Obviously, the accompanying drawings in the following descriptions are only some embodiments described in the present disclosure. For those ordinary skilled in the art, other accompanying drawings may also be obtained according to these accompanying drawings without exerting any creative effort.

FIG. 1 is a top view of a semiconductor device in a first embodiment of the present disclosure;

FIG. 2 is a schematic cross-sectional view taken along line AA in FIG. 1;

FIG. 3 is a schematic cross-sectional view taken along line BB in FIG. 1;

FIG. 4 is a flowchart of a method of manufacturing a semiconductor device in a second embodiment of the present disclosure;

FIG. 5 is a top view of a semiconductor device after step S20 is performed in the second embodiment of the present disclosure;

FIG. 6 is a schematic cross-sectional view taken along line AA in FIG. 5;

FIG. 7 is a top view of a semiconductor device after step S30 is performed in the second embodiment of the present disclosure;

FIG. 8 is a schematic cross-sectional view taken along line BB in FIG. 7;

FIG. 9 is a top view of a semiconductor device after step S40 is performed in the second embodiment of the present disclosure;

FIG. 10 is a schematic cross-sectional view taken along line AA in FIG. 9;

FIG. 11 is a top view of a semiconductor device after step S50 is performed in the second embodiment of the present disclosure;

FIG. 12 is a schematic cross-sectional view taken along line AA in FIG. 11;

FIG. 13 is a top view of a semiconductor device after step S101 is performed in the second embodiment of the present disclosure;

FIG. 14 is a schematic cross-sectional view taken along line AA in FIG. 13;

FIG. 15 is a top view of a semiconductor device after step S102 is performed in the second embodiment of the present disclosure;

FIG. 16 is a schematic cross-sectional view taken along line AA in FIG. 15;

FIG. 17 is a top view of a semiconductor device after step S103 is performed in the second embodiment of the present disclosure;

FIG. 18 is a schematic cross-sectional view taken along line AA in FIG. 17;

FIG. 19 is a top view of a semiconductor device after step S104 is performed in the second embodiment of the present disclosure;

FIG. 20 is a schematic cross-sectional view taken along line AA in FIG. 19;

FIG. 21 is a top view of a semiconductor device after step S105 is performed in the second embodiment of the present disclosure;

FIG. 22 is a schematic cross-sectional view taken along line AA in FIG. 21;

FIG. 23 is a top view of a semiconductor device after step S106 is performed in the second embodiment of the present disclosure;

FIG. 24 is a schematic cross-sectional view taken along line AA in FIG. 23;

FIG. 25 is a top view of a semiconductor device after step S107 is performed in the second embodiment of the present disclosure;

FIG. 26 is a schematic cross-sectional view taken along line AA in FIG. 25.

### DETAILED DESCRIPTION OF EMBODIMENTS

In order to enable those skilled in the art to better understand the technical solutions in one or more embodiments of the present disclosure, the technical solutions in one or more embodiments of the present disclosure will be clearly and completely described below in combination with the accompanying drawings in one or more embodiments of the present disclosure. Obviously, the described embodiments are only some embodiments of the present disclosure, but not all embodiments of the present disclosure. Based on one or more embodiments of the present disclosure, all other embodiments obtained without any creative effort by those ordinary skilled in the art should fall within the scope of protection of the present disclosure.

Dynamic Random Access Memory (DRAM) is the most widely used random access memory in the industry, and its mainstream structure is a combination of one Thin Film Transistor (TFT) and one Capacitance, that is, 1T1C. Oxide semiconductor is more and more widely used in TFT due to its excellent off-state current, which leads to a rise of 2T0C technology in DRAM. However, the oxide semiconductor has a relatively low relative on-state mobility rate of 3 cm²/Vs to 15 cm²/Vs, which leads to a small driving current of a transistor device in a working state, seriously affecting a reading and writing information rate of DRAM.

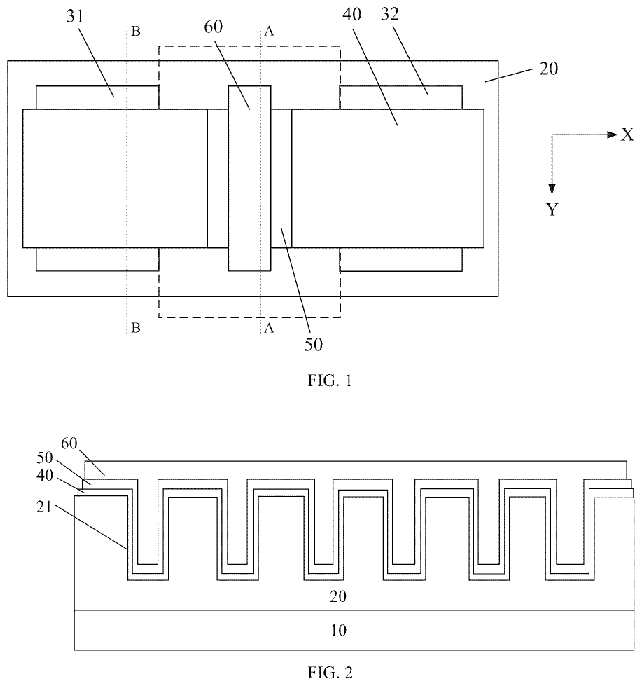

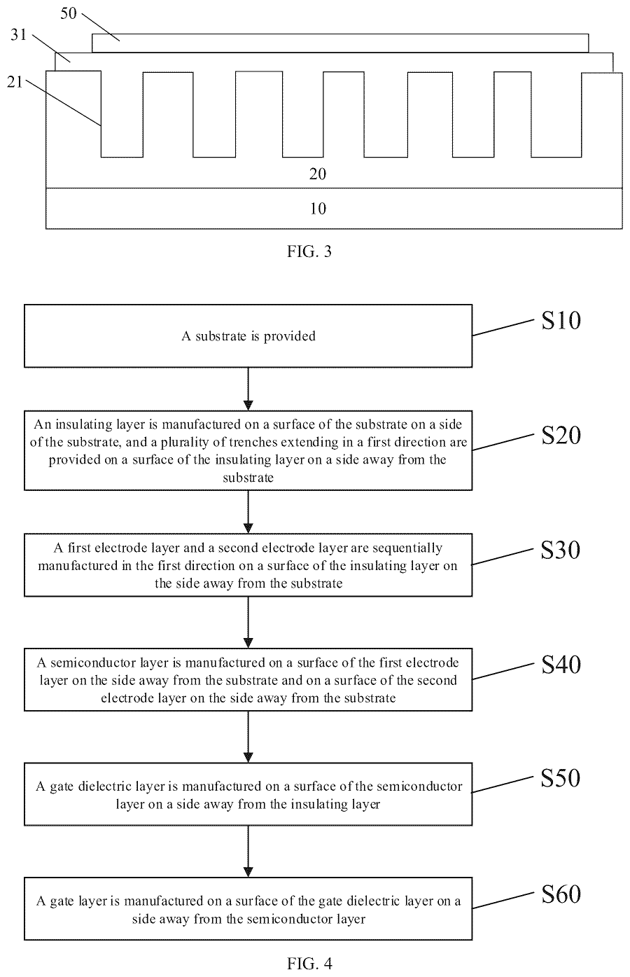

A first embodiment of the present disclosure provides a semiconductor device. In this embodiment, a width of an effective channel is improved through a design of a trench, so that a density of a driving current is improved. FIG. 1 is a top view of a semiconductor device in this embodiment. FIG. 2 is a schematic cross-sectional view taken along line AA in FIG. 1. FIG. 3 is a schematic cross-sectional view taken along line BB in FIG. 1.

As shown in FIG. 1 to FIG. 3, the semiconductor device in this embodiment mainly includes a substrate 10, an insulating layer 20, a first electrode layer 31, a second electrode layer 32, a semiconductor layer 40, a gate dielectric layer 50, and a gate layer 60. Specifically, the substrate 10 is mainly used to support and protect other layers, and is usually manufactured by a hard material. In this embodiment, the specific manufacturing material of the substrate 10 is not limited, and a corresponding material may be selected for manufacturing the substrate 10 according to actual needs. A main manufacturing material of the insulating layer 20 is any one of silicon dioxide SiO₂, silicon nitride SiN, carbon-containing silicon oxide SiCO, and silicon oxynitride SiON, or the insulating layer 20 is manufactured by other dielectric having a low dielectric constant. The insulating layer 20 is used to support other layers and achieve an insulation protection effect. In this embodiment, a plurality of trenches 21 extending in a first direction are provided on a surface (i.e., an upper surface of the insulating layer 20 in FIG. 2) of the insulating layer 20 on a side away from the substrate 10, and the plurality of trenches 21 are sequentially arranged in parallel in a second direction. In this embodiment, the first direction and the second direction are defined as directions perpendicular to each other in a plane where the substrate 10 is located. For example, a horizontal direction X in FIG. 1 is the first direction, and a vertical direction Y in FIG. 1 is the second direction. A horizontal direction in FIG. 2 and FIG. 3 corresponds to the second direction, that is, six trenches 21 are provided in the insulating layer 20 shown in FIG. 2 and FIG. 3.

In this embodiment, a width of the trench 21 may be in a range of 1 nm to 500 nm, such as 45 nm. A depth of the trench 21 may be in a range of 10 nm to 10000 nm, depending on a current density requirement as well as a processing capacity of high aspect ratio structure. For example, the depth of the trench 21 may be 90 nm, and a thickness of the corresponding insulating layer 20 may be greater than the depth of the trench 21, for example, the thickness of the insulating layer 20 may be 110 nm, so as to ensure that an upper surface of the substrate 10 may not be exposed after the trench is provided. Compared with a material of the substrate 10, a material of the insulating layer 20 is more conducive to a manufacturing of subsequent layers and a combination between layers. A spacing between two adjacent trenches 21 in the second direction may be in a range of 1 nm to 500 nm, such as 90 nm, which may be adjusted based on an actual arrangement density of the semiconductor device, an accuracy of a manufacturing process, etc.

It should be noted that the number of the trenches 21 and related manufacturing parameters shown in this embodiment are schematic, which may be adjusted based on requirements for a setting density, a device manufacturing process, a trench manufacturing process, a manufacturing cost, etc. of the semiconductor device in actual use.

The first electrode layer 31 and the second electrode layer 32 are provided in the first direction on the surface of the insulating layer 20 on the side away from the substrate 10. FIG. 1 shows an arrangement of the first electrode layer 31 and the second electrode layer 32. During a process of manufacturing the first electrode layer 31 and the second electrode layer 32, the trench 21 at a corresponding position may be filled with a metal material. As shown in FIG. 3, the electrode in the horizontal direction (i.e., on the upper surface of the insulating layer 20 in FIG. 3) and the vertical direction (i.e., filled in the trench 21 in FIG. 3) may be formed. In practical use of the semiconductor device, the first electrode layer 31 and the second electrode layer 32 are usually used as a source and a drain of the device respectively. When a channel is conducted, the source and the drain are conducted to achieve a transmission of a signal or data. Generally, the first electrode layer 31 and the second electrode layer 32 usually have lead-out ends for connecting with an input or output end of the signal. The specific design of the lead-out ends is carried out according to the actual use environment and requirements, which will not be limited in this embodiment.

When the first electrode layer 31 and the second electrode layer 32 are designed in practice, a spacing region (a portion shown by a dashed line box in FIG. 1) is provided between the first electrode layer 31 and the second electrode layer 32. That is, a metal layer is not designed on a surface of the insulating layer 20 corresponding to the spacing region, which is mainly used for providing a gate and its related layer. It should be understood that the spacing region delineated in this embodiment is only an example, and a position of the spacing region may change with a change in arrangement positions of the first electrode layer 31 and the second electrode layer 32. This embodiment will be described only in accordance with the schematic diagram of the semiconductor device structure shown in FIG. 1.

The semiconductor layer 40 is provided on a surface of the first electrode layer 31 on a side away from the insulating layer 20 and a surface of the second electrode layer 32 on the side away from the insulating layer 20 (i.e., the semiconductor layer 40 is provided on the upper surface of the insulating layer 20 in FIG. 2). The semiconductor layer 40 is used as a channel connecting the first electrode layer 31 with the second electrode layer 32. After the semiconductor layer 40 is manufactured, the semiconductor layer 40 simultaneously covers the surface of the first electrode layer 31, the surface of the second electrode layer 32 and a surface of the insulating layer 20 corresponding to the spacing region between the first electrode layer 31 and the second electrode layer 32. That is, an orthographic projection of the channel layer 40 on the substrate 10 has an overlapping region with each of an orthographic projection of the first electrode layer 31 on the substrate, an orthographic projection of the second electrode layer 32 on the substrate and an orthographic projection of the spacing region on the substrate. At the same time, the semiconductor layer 40 may cover a bottom portion of a channel trench and a sidewall of the channel trench, as shown in FIG. 2, forming a channel form in which a horizontal channel and a vertical channel are combined. The channel trench in this embodiment mainly refers to at least a part of trench bodies of the trenches 21 located in the spacing region. When a semiconductor material is grown or deposited based on the manufacturing process during actual manufacturing, a sidewall and a bottom portion of the trench in the spacing region, which is not covered by the metal layer, may be covered by the semiconductor material, and may be combined with a region covered by the semiconductor material on the upper surface of the metal layer, so as to form a connected semiconductor layer.

In some embodiments, the semiconductor layer 40 is mainly made of an indium gallium zinc oxide IGZO material, or may be made of other oxide semiconductors such as indium tin oxide ITO, etc., or may be made of a non-oxide semiconductor such as any one of silicon Si, germanium Ge, silicon germanium SiGe, gallium nitride GaN, gallium arsenide GaAs, and indium phosphide InP, which will not be specifically limited in this embodiment.

The gate dielectric layer 50 is provided on a surface of the semiconductor layer 40 on a side away from the insulating layer 20. The gate dielectric layer 50 is mainly provided in the spacing region, and used to achieve an insulation between the gate layer 60 and the semiconductor layer 40. That is, an orthographic projection of the gate dielectric layer 50 on the substrate 10 has an overlapping region with the orthographic projection of the spacing region on the substrate 10, and the orthographic projection of the gate dielectric layer 50 on the substrate 10 has no overlapping region with each of the orthographic projection of the first electrode layer 31 on the substrate 10 and the orthographic projection of the second electrode layer 32 on the substrate 10. At the same time, during the manufacturing, the gate dielectric layer 50 also covers a surface of the existing semiconductor layer 40 in the channel trench, that is, the gate dielectric layer 50 covers a surface of the semiconductor layer 40 in the channel trench on a side away from the bottom portion and the sidewall of the channel trench. In some embodiments, the gate dielectric layer 50 is manufactured based on any one of: aluminium oxide Al₂O₃, hafnium dioxide HfO₂, alumina hafnium HfAIO, zirconia hafnium HfZrO, silicon nitride SiN, silicon dioxide SiO₂, and silicon oxynitride SiON.

The gate layer 60 is located on a surface (i.e., the upper surface of the gate dielectric layer 50 in FIG. 2) of the gate dielectric layer 50 on a side away from the semiconductor layer 40. That is, an orthographic projection of the gate layer 60 on the substrate 10 has an overlapping region with the orthographic projection of the spacing region on the substrate 10. As shown in FIG. 2, at least a part of the channel trenches may be fully filled with the gate layer 60, so as to form a complete gate layer plane on the surface of the gate dielectric layer 50. When a gate voltage is applied to the gate layer 60, the semiconductor layer 40 may form a conductive channel between the first electrode layer 31 and the second electrode layer 32, and electrons flow in the channel to achieve a connection between the first electrode layer 31 and the second electrode layer 32, so as to form a driving current.

In some embodiments, each of the gate layer 60, the first electrode layer 31, and the second electrode layer 32 may be manufactured based on any one of the following materials: tungsten W, molybdenum Mo, tantalum Ta, titanium nitride TiN, tantalum nitride TaN, gold Au, and platinum Pt, or may be manufactured using other materials with good electrical conductivity.

It should be understood that, in addition to an on-state mobility rate of the semiconductor material itself, a magnitude of the driving current is also related to a length and a width of the effective channel. In this embodiment, the length of the effective channel is equivalent to a spacing between the first electrode layer 31 and the second electrode layer 32, that is, a distance that the electrons need to move. The longer the distance, the smaller a value of the driving current. In a case that the length of the effective channel does not change, a wider width of the effective channel is equivalent to more channels for the electrons to move, and the value of the driving current may also increase. In this embodiment, by providing the trench, the width of the effective channel is improved by a combination of the horizontal channel and the vertical channel, a density of the driving current is improved, thereby achieving an effect of improving the reading and writing information rate of the memory device.

A second embodiment of the present disclosure provides a method of manufacturing a semiconductor device, which is mainly used for manufacturing the semiconductor device in the first embodiment of the present disclosure. The flowchart of the method is shown in FIG. 4, which mainly includes steps S10 to S60.

In step S10, a substrate is provided.

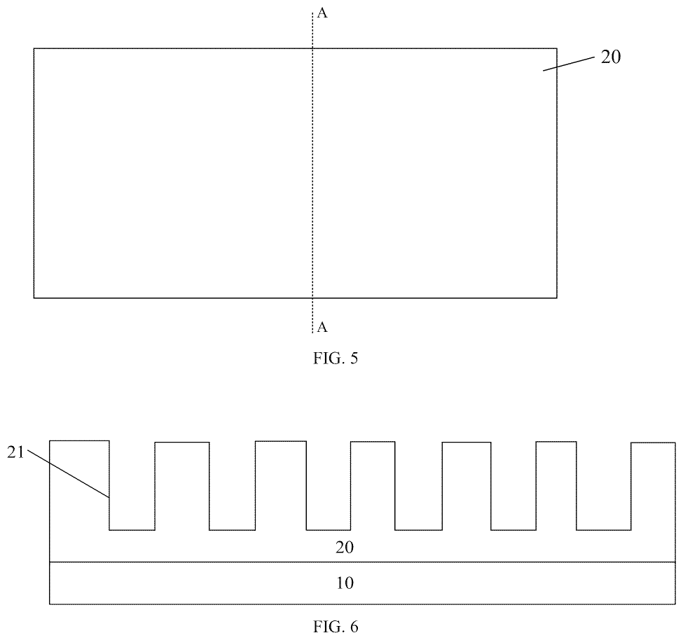

In step S20, an insulating layer is manufactured on a surface of the substrate on a side of the substrate, and a plurality of trenches extending in a first direction are provided on a surface of the insulating layer on a side away from the substrate; where the plurality of trenches are sequentially arranged in parallel in a second direction, and the first direction and the second direction are directions perpendicular to each other in a plane where the substrate is located. At this time, a top view of the corresponding semiconductor device is shown in FIG. 5, and a corresponding schematic cross-sectional view taken along line AA in FIG. 5 is shown in FIG. 6.

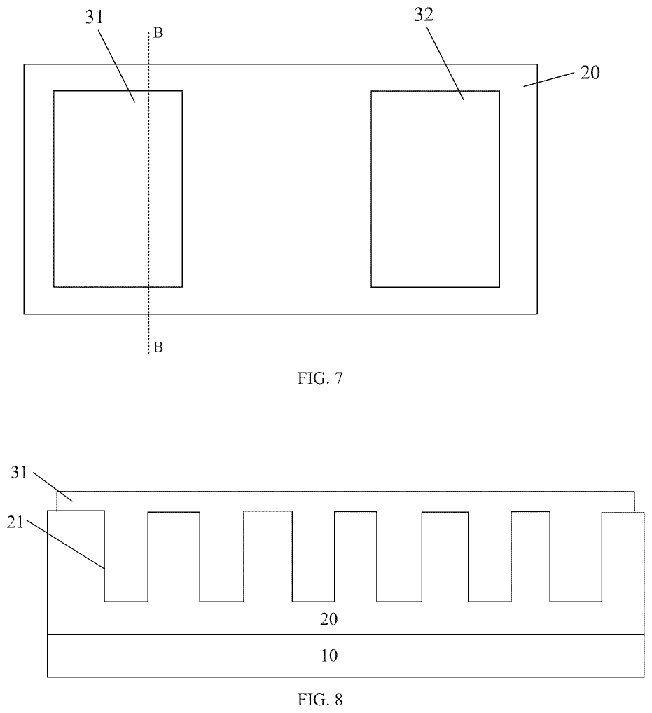

In step S30, a first electrode layer and a second electrode layer are sequentially manufactured in the first direction on a surface of the insulating layer on the side away from the substrate; where a spacing region is provided between the first electrode layer and the second electrode layer. At this time, a top view of the corresponding semiconductor device is shown in FIG. 7, and a corresponding schematic cross-sectional view taken along line BB in FIG. 7 is shown in FIG. 8.

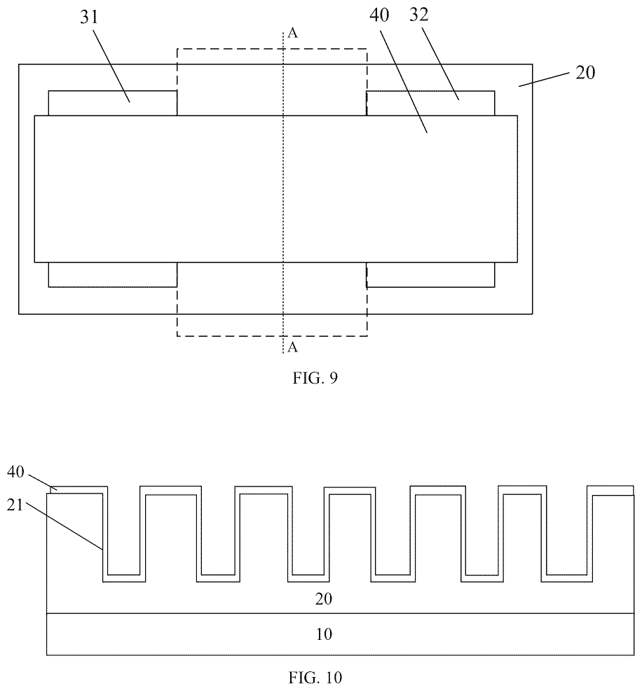

In step S40, a semiconductor layer is manufactured on a surface of the first electrode layer on the side away from the substrate and on a surface of the second electrode layer on the side away from the substrate; where an orthographic projection of the semiconductor layer on the substrate has an overlapping region with each of an orthographic projection of the first electrode layer on the substrate, an orthographic projection of the second electrode layer on the substrate and an orthographic projection of the spacing region on the substrate, the semiconductor layer covers bottom portions and sidewalls of all channel trenches, and the channel trenches are at least the part of trench bodies of the trenches located in the spacing region. At this time, a top view of the corresponding semiconductor device is shown in FIG. 9, and a corresponding schematic cross-sectional view taken along line AA in FIG. 9 is shown in FIG. 10.

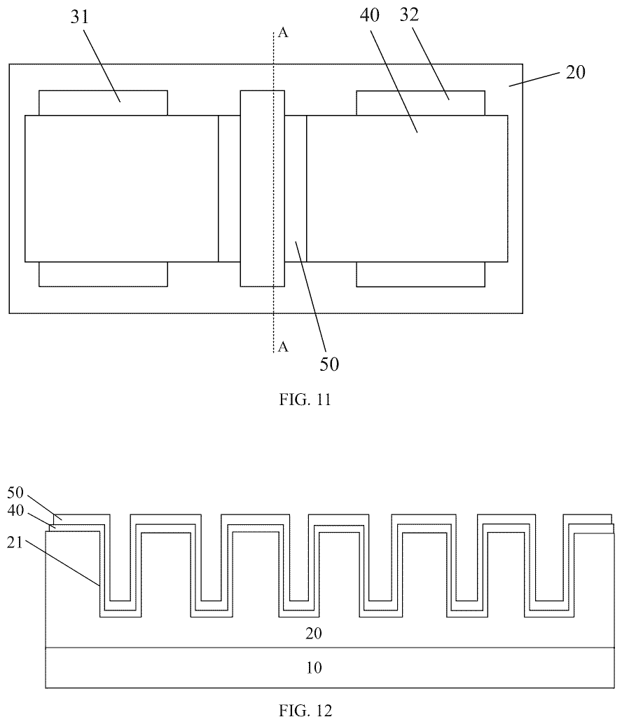

In step S50, a gate dielectric layer is manufactured on a surface of the semiconductor layer on a side away from the insulating layer; where an orthographic projection of the gate dielectric layer on the substrate has an overlapping region with the orthographic projection of the spacing region on the substrate, the orthographic projection of the gate dielectric layer on the substrate has no overlapping region with each of the orthographic projection of the first electrode layer on the substrate and the orthographic projection of the second electrode layer on the substrate, and the gate dielectric layer covers the surface of the semiconductor layer in the channel trenches on the side away from the bottom portions and the sidewalls of the channel trenches. At this time, a top view of the corresponding semiconductor device is shown in FIG. 11, and a corresponding schematic cross-sectional view taken along line AA in FIG. 11 is shown in FIG. 12.

In step S60, a gate layer is manufactured on a surface of the gate dielectric layer on a side away from the semiconductor layer; where an orthographic projection of the gate layer on the substrate has an overlapping region with the orthographic projection of the spacing region on the substrate, and at least a part of the channel trenches are fully filled with the gate layer. At this time, a top view of the corresponding semiconductor device is shown in FIG. 1, and a corresponding schematic cross-sectional view taken along line AA in FIG. 1 is shown in FIG. 2.

In some embodiments, a process of manufacturing the trench on the insulating layer may be any one of a dual patterning and sacrificial layer removal process, a multiple patterning process, and a photolithography process. Accordingly, for the reasons of characteristics of the process, an accuracy of the apparatus, etc., the width of the trench and the spacing between trenches manufactured by different processes may also be different, and may be selected according to actual needs.

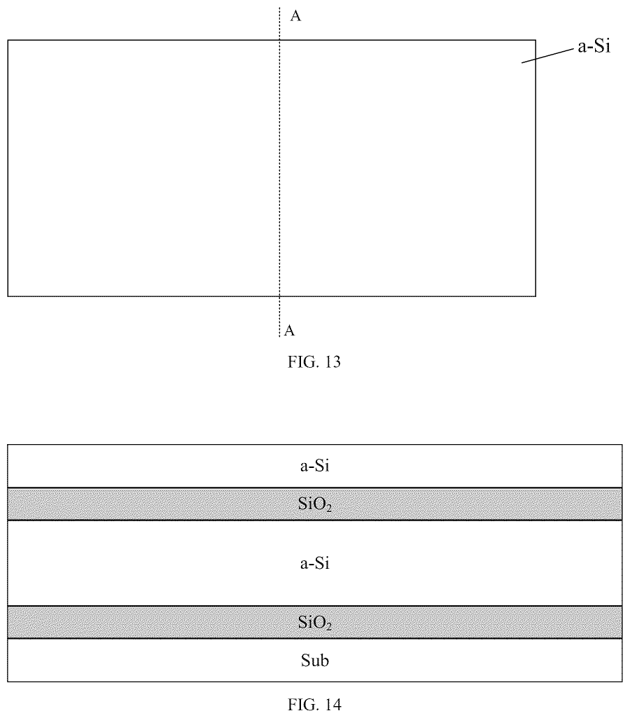

In combination with FIG. 13 to FIG. 26, in a case that the trenches are manufactured on the insulating layer by using the dual patterning and sacrificial layer removal process, the steps of manufacturing the semiconductor device will be briefly described below, including steps S101 to S111.

In step S101, a first dielectric SiO₂ layer with a thickness of 25 nm, a first amorphous silicon a-Si layer with a thickness of 200 nm, a second dielectric SiO₂ layer with a thickness of 5 nm and a second amorphous silicon a-Si layer with a thickness of 100 nm are sequentially grown on a substrate Sub. A corresponding top view and a corresponding cross-sectional view taken along line AA are shown in FIG. 13 and FIG. 14, respectively.

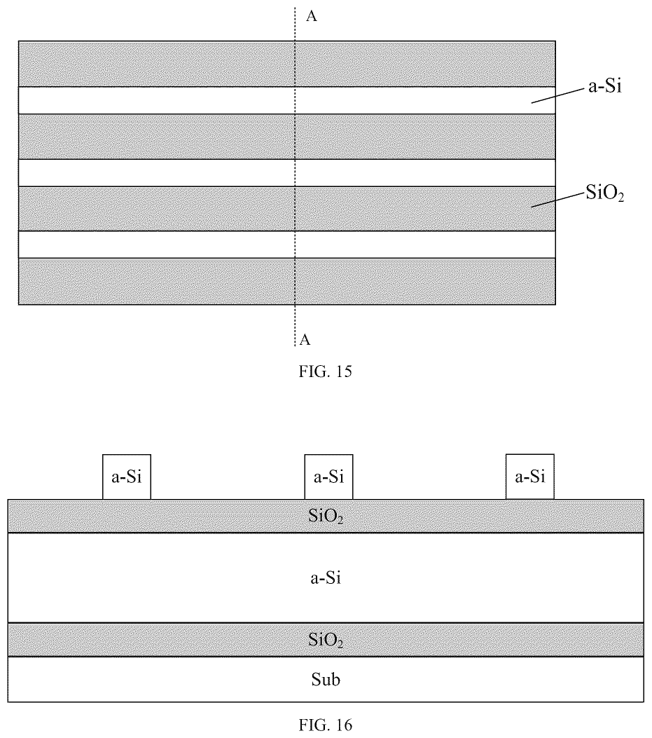

In step S102, photolithography and anisotropic etching are performed on the second amorphous silicon a-Si layer, and the etching stops on a surface of the second dielectric SiO₂ layer, so as to form a strip-shaped a-Si pattern. A pattern CD depends on a process capability, such as a line width of 90 nm and a spacing of 180 nm. A corresponding top view and a corresponding cross-sectional view taken along line AA are shown in FIG. 15 and FIG. 16, respectively.

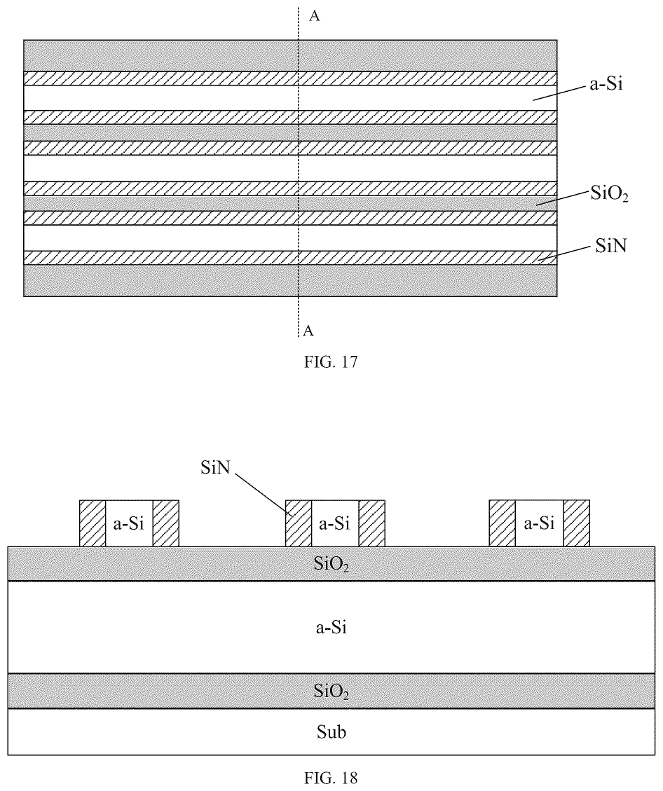

In step S103, a SiN thin film is grown and anisotropically etched, and the etching stops on the surface of the second dielectric SiO₂ layer, so as to form a strip-shaped SiN pattern. A thickness of SiN is determined as required. In this embodiment, the thickness of SiN is 45 nm, and a process of growing the SiN thin film is achieved by LPCVD, PECVD or ALD. A corresponding top view and a corresponding cross-sectional view taken along line AA are shown in FIG. 17 and FIG. 18, respectively.

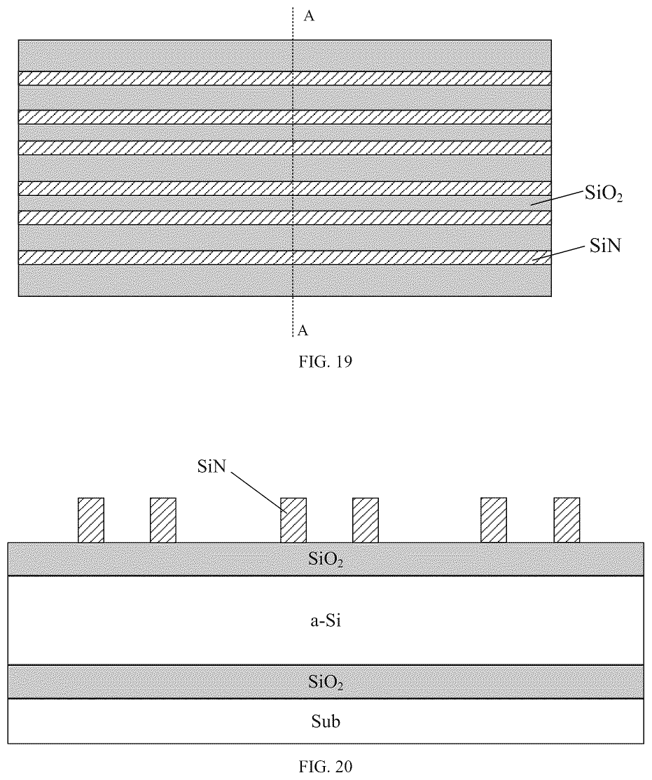

In step S104, the second amorphous silicon a-Si layer is selectively removed by wet TMAH or dry halogen gas etching. A corresponding top view and a corresponding cross-sectional view taken along line AA are shown in FIG. 19 and FIG. 20, respectively.

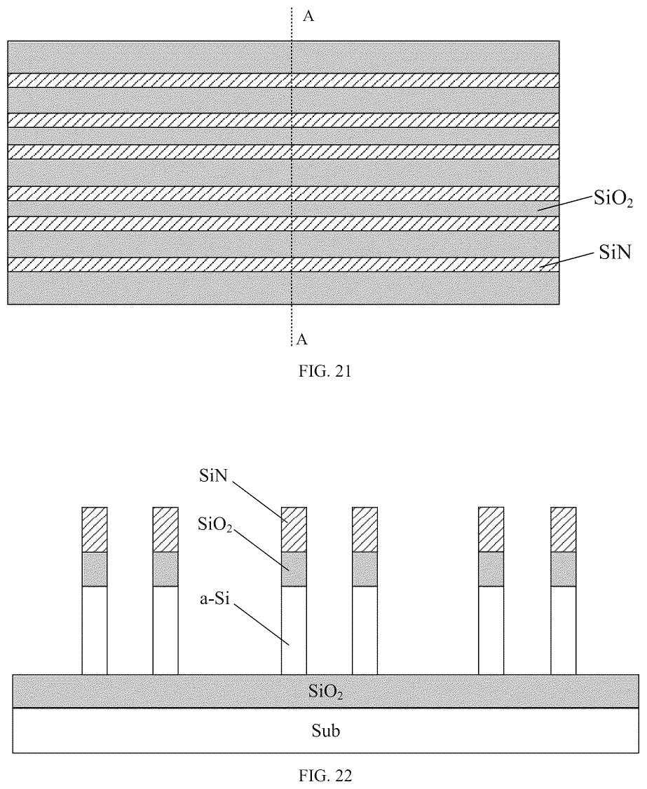

In step S105, the anisotropic etching is performed on the second dielectric SiO₂ layer and the first amorphous silicon a-Si layer, and the etching stops on a surface of the first dielectric SiO₂ layer. A corresponding top view and a corresponding cross-sectional view taken along line AA are shown in FIG. 21 and FIG. 22, respectively. At this time, SiO₂ marked in FIG. 21 corresponds to the first SiO₂ layer.

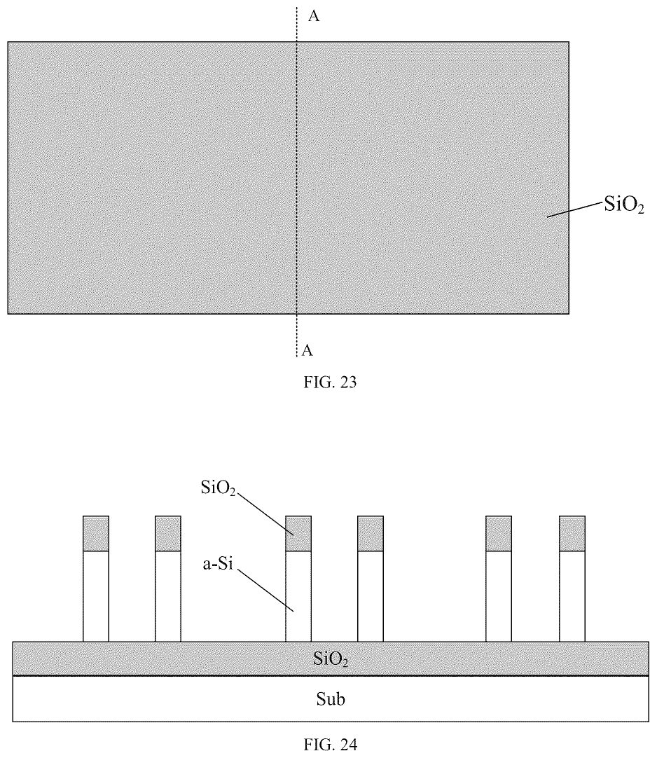

In step S106, the SiN thin film layer is selectively removed by, for example, 150° C. thermal phosphoric acid. A corresponding top view and a corresponding cross-sectional view taken along line AA are shown in FIG. 23 and FIG. 24, respectively. At this time, the first SiO₂ layer and the remaining part of the second SiO₂ layer are shown in FIG. 23.

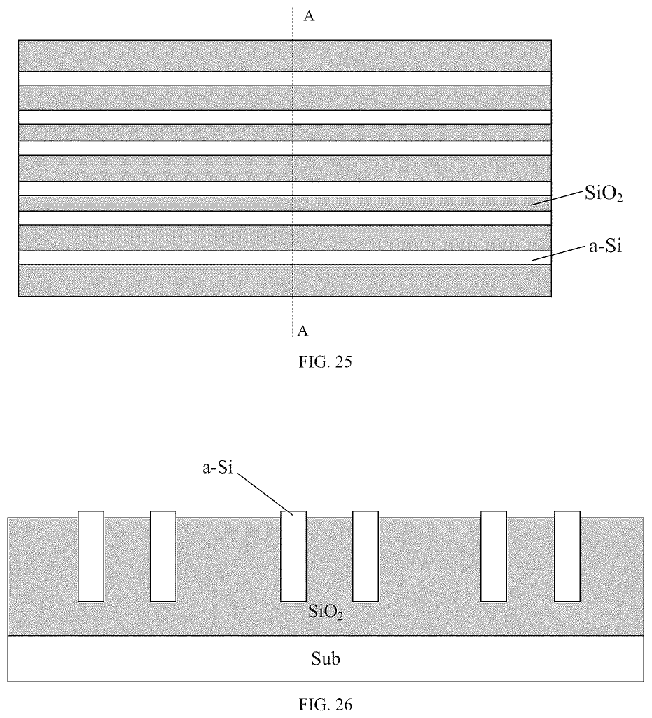

In step S107, the dielectric SiO₂ is filled and planarized, and then the dielectric SiO₂ is etched back so that a top portion of the first a-Si layer is exposed. The filling process may use an HARP process, the planarization process may use CMP, and the etching back process may use DHF or BOE. A corresponding top view and a corresponding cross-sectional view taken along line AA are shown in FIG. 25 and FIG. 26, respectively.

In step S108, the first a-Si layer is selectively removed by wet TMAH or dry halogen gas etching. A corresponding top view and a corresponding cross-sectional view taken along line AA are shown in FIG. 5 and FIG. 6, respectively.

In step S109, a metal with a thickness of 100 nm, preferably Mo or W, is deposited by PVD, CVD or ALD.

In step S110, an IGZO layer with a thickness of 8 nm is deposited by ALD, and a pattern is etched.

In step S111, a gate dielectric layer, preferably Al₂O₃ with a thickness of 5 nm, is deposited by ALD. A gate metal with a thickness of preferably 30 nm, preferably W (or Mo), is deposited by ALD to fill the trench. A gate pattern is obtained by photolithography and etching.

In this embodiment, without affecting the length of the effective channel of the semiconductor device and the horizontal area of the semiconductor device, the width of the effective channel is increased by providing the trench, and the density of the driving current is improved by a combination of the horizontal channel and the vertical channel, thereby achieving the improvement of the reading and writing information rate of the memory device.

Finally, it should be noted that, the above-mentioned embodiments are only used to describe the technical solutions of the present disclosure, but not to limit the present disclosure. Although the present disclosure has been described in detail with reference to the above-mentioned embodiments, those ordinary skilled in the art should understand that modifications may be made to the technical solutions described in the above-mentioned embodiments, or equivalent substitutions may be made to some or all of the technical features thereof. These modifications or substitutions do not make the essence of the corresponding technical solutions deviate from the scope of the technical solutions of the embodiments of the present disclosure.

What is claimed is:

1. A semiconductor device, comprising:
a substrate;
an insulating layer provided on a surface of the substrate on a side of the substrate, wherein the insulating layer is provided with a plurality of trenches extending in a first direction, the plurality of trenches are sequentially arranged in parallel in a second direction, and the first direction and the second direction are directions perpendicular to each other in a plane where the substrate is located;
a first electrode layer and a second electrode layer sequentially provided in the first direction on a surface of the insulating layer on a side away from the substrate, wherein a spacing region is provided between the first electrode layer and the second electrode layer;
a semiconductor layer provided on a surface of the first electrode layer on the side away from the substrate and provided on a surface of the second electrode layer on the side away from the substrate, wherein an orthographic projection of the semiconductor layer on the substrate has an overlapping region with each of an orthographic projection of the first electrode layer on the substrate, an orthographic projection of the second electrode layer on the substrate and an orthographic projection of the spacing region on the substrate, the semiconductor layer covers bottom portions and sidewalls of all channel trenches, and the channel trenches are at least a part of trench bodies of the trenches located in the spacing region;
a gate dielectric layer provided on a surface of the semiconductor layer on a side away from the insulating layer, wherein an orthographic projection of the gate dielectric layer on the substrate has an overlapping region with the orthographic projection of the spacing region on the substrate, the orthographic projection of the gate dielectric layer on the substrate has no overlapping region with each of the orthographic projection of the first electrode layer on the substrate and the orthographic projection of the second electrode layer on the substrate, and the gate dielectric layer covers a surface of the semiconductor layer in the channel trenches on a side away from the bottom portions and the sidewalls of the channel trenches; and
a gate layer provided on a surface of the gate dielectric layer on a side away from the semiconductor layer, wherein an orthographic projection of the gate layer on the substrate has an overlapping region with the orthographic projection of the spacing region on the substrate, and at least a part of the channel trenches are fully filled with the gate layer.

2. The semiconductor device according to claim 1, wherein a width of the trench is in a range of 1 nm to 500 nm.

3. The semiconductor device according to claim 1, wherein a depth of the trench is in a range of 10 nm to 10000 nm.

4. The semiconductor device according to claim 1, wherein a spacing between two adjacent trenches in the second direction is in a range of 1 nm to 500 nm.

5. The semiconductor device according to claim 1, wherein the gate dielectric layer is manufactured based on one of:
aluminium oxide Al₂O₃, hafnium dioxide HfO₂, alumina hafnium HfAIO, zirconia hafnium HfZrO, silicon nitride SiN, silicon dioxide SiO₂, and silicon oxynitride SION.

6. The semiconductor device according to claim 1, wherein each of the gate layer, the first electrode layer, and the second electrode layer is manufactured based on one of:
tungsten W, molybdenum Mo, tantalum Ta, titanium nitride TiN, tantalum nitride TaN, gold Au, and platinum Pt.

7. The semiconductor device according to claim 1, wherein the semiconductor layer is manufactured based on one of:
indium gallium zinc oxide IGZO, indium tin oxide ITO, silicon Si, germanium Ge, silicon germanide SiGe, gallium nitride GaN, gallium arsenide GaAs, and indium phosphide InP.

8. The semiconductor device according to claim 1, wherein the insulating layer is manufactured based on one of:
silicon dioxide SiO₂, silicon nitride SiN, carbon-containing silicon oxide SiCO, and silicon oxynitride SION.

9. A method of manufacturing the semiconductor device according to claim 1, comprising:
providing the substrate;
manufacturing the insulating layer on the surface of the substrate on the side of the substrate, and providing the plurality of trenches extending in the first direction on the surface of the insulating layer on the side away from the substrate, wherein the plurality of trenches are sequentially arranged in parallel in the second direction, and the first direction and the second direction are directions perpendicular to each other in the plane where the substrate is located;
sequentially manufacturing the first electrode layer and the second electrode layer in the first direction on the surface of the insulating layer on the side away from the substrate, wherein the spacing region is provided between the first electrode layer and the second electrode layer;
manufacturing the semiconductor layer on the surface of the first electrode layer on the side away from the substrate and on the surface of the second electrode layer on the side away from the substrate, wherein the orthographic projection of the semiconductor layer on the substrate has the overlapping region with each of the orthographic projection of the first electrode layer on the substrate, the orthographic projection of the second electrode layer on the substrate and the orthographic projection of the spacing region on the substrate, the semiconductor layer covers bottom portions and sidewalls of all channel trenches, and the channel trenches are at least the part of trench bodies of the trenches located in the spacing region;
manufacturing the gate dielectric layer on the surface of the semiconductor layer on the side away from the insulating layer, wherein the orthographic projection of the gate dielectric layer on the substrate has the overlapping region with the orthographic projection of the spacing region on the substrate, the orthographic projection of the gate dielectric layer on the substrate has no overlapping region with each of the orthographic projection of the first electrode layer on the substrate and the orthographic projection of the second electrode layer on the substrate, and the gate dielectric layer covers the surface of the semiconductor layer in the channel trenches on the side away from the bottom portions and the sidewalls of the channel trenches; and
manufacturing the gate layer on the surface of the gate dielectric layer on the side away from the semiconductor layer, wherein the orthographic projection of the gate layer on the substrate has the overlapping region with the orthographic projection of the spacing region on the substrate, and at least the part of the channel trenches are fully filled with the gate layer.

10. The method according to claim 9, wherein the trenches are provided on the surface of the insulating layer on the side away from the substrate based on one of:
a dual patterning and sacrificial layer removal process, a multiple patterning process, and a photolithography process.
